(19) United States
(12) Patent Application Publication
(10) Pub. No.: US 2021/0336107 A1
(43) Pub. Date: Oct. 28, 2021

(54) DISPLAY PANEL AND METHOD OF FABRICARING SAME, AND DISPLAY DEVICE

(71) Applicant: SHENZHEN CHINA STAR OPTOELECTRONICS SEMICONDUCTOR DISPLAY TECHNOLOGY CO., LTD., Shenzhen (CN)

(72) Inventors: Bei JIANG, Shenzhen (CN); Yong FAN, Shenzhen (CN); Minggang LIU, Shenzhen (CN)

(73) Assignee: SHENZHEN CHINA STAR OPTOELECTRONICS SEMICONDUCTOR DISPLAY TECHNOLOGY CO., LTD., Shenzhen (CN)

(21) Appl. No.: 16/626,351

(22) PCT Filed: Nov. 26, 2019
(86) PCT No.: PCT/CN2019/120952

§ 371 Date: Dec. 24, 2019

(30) Foreign Application Priority Data
Nov. 7, 2019 (CN) 201911080879.4

(51) Int. Cl. H01L 33/62; H01L 27/15; H01L 33/00

(52) U.S. Cl. CPC H01L 33/62; H01L 2933/0066; H01L 33/005; H01L 27/156

(57) ABSTRACT

A display panel and a method of fabricating the same, and a display device are provided. The display panel has: a first substrate having a first lead at a first edge of the first substrate and a second lead at a second edge of the first substrate; a second substrate having a third lead at a third edge of the second substrate and a fourth lead at a fourth edge of the second substrate; and connection lines connected the first lead to the fourth lead and connected the second lead to the third lead.

### CROSS REFERENCE TO RELATED APPLICATION

This application claims priority to a Chinese patent application filed with the China National Intellectual Property Administration on Nov. 7, 2019, with an application number of 201911080879.4, and a disclosure name is “DISPLAY PANEL AND METHOD OF FABRICARING SAME, AND DISPLAY DEVICE”, an entire contents of which are incorporated herein by reference.

### FIELD OF DISCLOSURE

The present disclosure relates to displays, and more particularly to a display panel and a method of fabricating the same, and a display device.

### BACKGROUND OF DISCLOSURE

A micro light emitting diode (Micro-LED) is to reduce size of a traditional light emitting diode chip to less than 100 micrometers, and then to transfer red, green, and blue three-color chips to a thin-film transistor driving circuit back plate in batches by using transfer technology, so as to form an array structure. Positive and negative electrodes of the chips are connected to source and drain of the back plate. Brightness and darkness are controlled by red, green, and blue pixels control to achieve a purpose of full color display. Micro-LED has advantages of self-luminous, not easily affected by water vapor, oxygen or high temperature.

In conventional technologies, when a micro-LED is applied to a large screen or an ultra-large screen (for example, larger than 100 square meters), due to a relatively large side frame of a Micro-LED display panel, when a screen unit is spliced, there will be a large black non-light-emitting region, which will affect a user's visual experience.

Therefore, a display panel is urgently needed to solve the above technical problems.

### SUMMARY OF DISCLOSURE

The present application provides a display panel and a method of fabricating the same, and a display device to solve technical problems of leaving a relatively large black non-light-emitting region when splicing large screens.

A display panel, comprising:
a first substrate comprising a first base, a first power line layer on the first base, and at least one light emitting device on the first power line layer, wherein the first power line layer comprises:
   a first lead located at a first edge of the first base; and
   a second lead located at a second edge of the first base;
a second substrate located at a side of the first substrate away from the light emitting device and comprising a second base and a second power line layer at a side of the second base away from the light emitting device, wherein the second power line layer comprises:
   a first fan-out wiring region comprising first fan-out wirings and a third lead located at a third edge of the second substrate; and
   a second fan-out wiring region comprising second fan-out wirings and a fourth lead located at a fourth edge of the second substrate;
a first connection line located on a side vertical surface of the first base along the first edge to electrically connect the first lead to the fourth lead; and
a second connection line located on a side vertical surface of the second base along the second edge to electrically connect the second lead to the third lead.

In a display panel of the present application, the first lead is vertically drawn from the first edge and is collinear with a scan line in the first power line layer;
the second lead is vertically drawn from the second edge and is collinear with a data line in the first power line layer;
the third lead is vertically drawn from the third edge and is electrically connected to one of the first fan-out wirings;
the fourth lead is vertically drawn from the fourth edge and is electrically connected to one of the second fan-out wirings;
the first edge is vertical to the second edge, and the third edge is vertical to the fourth edge; and
the first edge is aligned with the fourth edge, and the second edge is aligned with the third edge.

In a display panel of the present application, the first lead and the fourth lead are symmetrical with respect to a symmetry plane of the first base and the second base; and
the second lead and the third lead are symmetrical with respect to the symmetry plane of the first base and the second base.

In a display panel of the present application, length of the first lead, the second lead, the third lead, and the fourth lead is smaller than a pitch between two adjacent light emitting devices.

In a display panel of the present application, the light emitting device comprises micro-LED and mini-LED.

In a display panel of the present application, the display panel further comprises a circuit board layer on the second power line layer,
wherein the circuit board layer comprises a flip-chip thin film and a printed wiring board.

The present application further provides a display device, comprising at least two display panels,
wherein each of the display panels comprises:
a first substrate comprising a first base, a first power line layer on the first base, and at least one light emitting device on the first power line layer, wherein the first power line layer comprises:
   a first lead located at a first edge of the first base; and
   a second lead located at a second edge of the first base;
a second substrate located at a side of the first substrate away from the light emitting device and comprising a second base and a second power line layer at a side of the second base away from the light emitting device, wherein the second power line layer comprises:
   a first fan-out wiring region comprising first fan-out wirings and a third lead located at a third edge of the second substrate; and
   a second fan-out wiring region, comprising second fan-out wirings and a fourth lead located at a fourth edge of the second substrate;
a first connection line located on a side vertical surface of the first base along the first edge to electrically connect the first lead to the fourth lead; and
a second connection line located on a side vertical surface of the second base along the second edge to electrically connect the second lead to the third lead.

In a display device of the present application, the first lead is vertically drawn from the first edge and is collinear with a scan line in the first power line layer;
the second lead is vertically drawn from the second edge and is collinear with a data line in the first power line layer;
the third lead is vertically drawn from the third edge and is electrically connected to one of the first fan-out wirings;
the fourth lead is vertically drawn from the fourth edge and is electrically connected to one of the second fan-out wirings;
the first edge is vertical to the second edge, and the third edge is vertical to the fourth edge; and
the first edge is aligned with the fourth edge, and the second edge is aligned with the third edge.

In a display device of the present application, the first lead and the fourth lead are symmetrical with respect to a symmetry plane of the first base and the second base; and
the second lead and the third lead are symmetrical with respect to the symmetry plane of the first base and the second base.

In a display device of the present application, length of the first lead, the second lead, the third lead, and the fourth lead is smaller than a pitch between two adjacent light emitting devices.

In a display device of the present application, the light emitting device comprises micro-LED and mini-LED.

In a display device of the present application, each of the display panels further comprises a circuit board layer on the second power line layer,
wherein the circuit board layer comprises a flip-chip thin film and a printed wiring board.

In a display device of the present application,
a pitch between two adjacent light emitting devices between two adjacent display panels is smaller than a pitch between the two adjacent light emitting devices in any one of the display panels.

The present application further provides a method of fabricating a display panel, comprising steps of:
forming a first power line layer on a first base, wherein:
   the first power line layer comprises a first lead located at a first edge of the first base and a second lead located at a second edge of the first base;
forming a second power line layer on a second base, the second power line layer comprising a first fan-out wiring region and a second fan-out wiring region, wherein:
   the first fan-out wiring region comprises first fan-out wirings and a third lead located at a third edge of the second base; and the second fan-out wiring region comprises second fan-out wirings and a fourth lead located at a fourth edge of the second base;
bonding a side of the first base away from the first power line layer to a side of the second base away from the second power line layer;
forming a first connection line on a side vertical surface of the first base along the first edge to electrically connect the first lead to the fourth lead, and forming a second connection line on a side vertical surface of the second base along the third edge to electrically connect the second lead to the third lead; and
forming at least one light emitting device on the first power line layer.

In a method of fabricating a display panel of the present application, the step of forming the first power line layer on the first base comprises:
forming scan lines insulated from each other along a first direction on the first base, and forming the first lead extending from one of the scan lines and vertical to the first edge of the first base; and
forming data lines insulated from each other along a second direction on the first base, and forming the second lead extending from one of the data lines and vertical to the second edge of the first base,
wherein the first edge is vertical to the second edge.

In a method of fabricating a display panel of the present application, the step of forming the second power line layer on the second base comprises:
forming the first fan-out wirings insulated from each other on the second base, and forming the third lead extending from one of the first fan-out wirings and vertical to the third edge of the second base; and
forming the second fan-out wirings insulated from each other on the second base, and forming the fourth lead extending from one of the second fan-out wirings and vertical to the fourth edge of the second base, wherein the third edge is vertical to the fourth edge, the first edge is aligned with the fourth edge, and the second edge is aligned with the third edge; and
the first lead and the fourth lead are symmetrical with respect to a symmetry plane of the first base and the second base, and the second lead and the third lead are symmetrical with respect to the symmetry plane of the first base and the second base.

In a method of fabricating a display panel of the present application, length of the first lead, the second lead, the third lead, and the fourth lead is smaller than a pitch between two adjacent light emitting devices.

In a method of fabricating a display panel of the present application, the method of fabricating the display panel further comprises steps of:
forming a circuit board layer on the second power line layer,
wherein the circuit board layer comprises a flip-chip thin film and a printed wiring board.

In a method of fabricating a display panel of the present application, the light emitting device comprises micro-LED and mini-LED.

In the present application, fan-out wirings are provided on a back of the display panel, and data lines and scan lines are electrically connected to the fan-out wirings through leads and connection lines, thereby realizing a frameless design of the display panel, facilitating the display panel splicing, reducing a black non-display region of a splicing screen, and improving a user's experience.

### DESCRIPTION OF DRAWINGS

FIG. 1 is a first structural diagram of a display panel of the present application;

FIG. 2 is a partial top view of a first structural diagram of a display panel of the present application;

FIG. 3 is a partial top view of a first structural diagram of a display panel of the present application;

FIG. 4 is a symmetrical schematic diagram of a second structure of a display panel of the present application;

FIG. 5 is a partial top view of a display device of the present application; and

FIG. 6 is a fabricating flowchart of a display panel of the present application.

### DETAILED DESCRIPTION OF PREFERRED EMBODIMENTS

In order to make purposes, technical solutions, and effects of the present application more clear and definite, the present application is further described in detail below with reference to the drawings and examples. It should be understood that the specific embodiments described herein are only used to explain the application, and are not used to limit the application.

In conventional technologies, when a micro-LED is applied to a large screen or an ultra-large screen (for example, larger than 100 square meters), due to a relatively large side frame of a Micro-LED display panel, when a screen unit is spliced, there will be a large black non-light-emitting region, which will affect a user's visual experience. Based on this, the present application provides a display panel, a display device, and a method of fabricating the display panel.

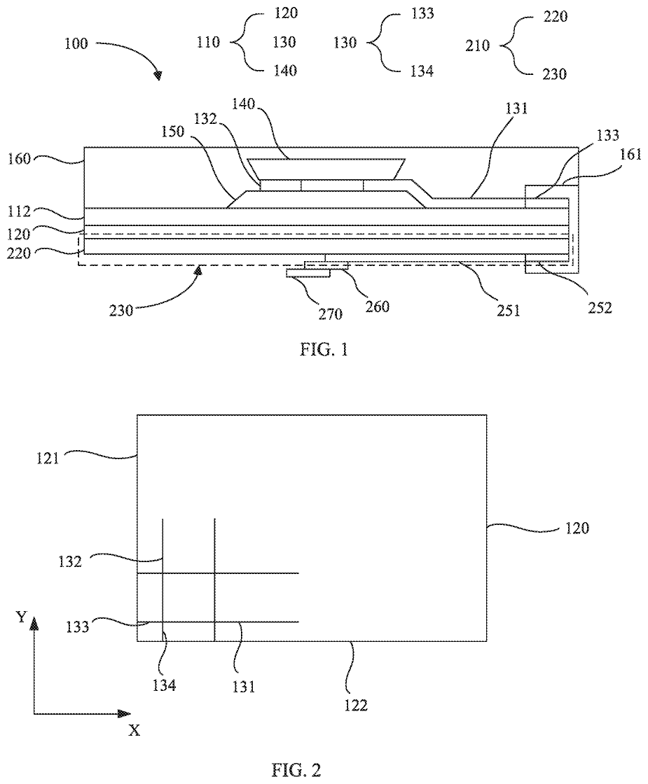

Referring to FIG. 1 to FIG. 4, the display panel 100 comprises:

A first substrate 110 comprises a first base 120, a first power line layer 130 on the first base 120, and at least one light emitting device 140 on the first power line layer 130, wherein the first power line layer 130 comprises: a first lead 133 located at a first edge 121 of the first base 120; and a second lead 134 located at a second edge 122 of the first base 120.

A second substrate 210 is located at a side of the first substrate 210 away from the light emitting device 140 and comprises a second base 220 and a second power line layer 230 at a side of the second base 220 away from the light emitting device 140. The second power line layer 230 comprises a first fan-out wiring region and a second fan-out wiring region. The first fan-out wiring region comprises first fan-out wirings 241 and a third lead 242 located at a third edge 221 of the second substrate 210. The second fan-out wiring region comprises second fan-out wirings 251 and a fourth lead 252 located at a fourth edge 222 of the second substrate 210.

A first connection line 161 is located on a side vertical surface of the first base 120 along the first edge 121 to electrically connect the first lead 133 to the fourth lead 252.

A second connection line 162 is located on a side vertical surface of the second base 220 along the second edge 122 to electrically connect the second lead 134 to the third lead 242.

In the present application, fan-out wirings are provided on a back of the display panel, and power lines on a front of the display panel are electrically connected to the fan-out wirings through leads and connection lines, thereby realizing a frameless design of the display panel, facilitating the display panel splicing, reducing a black non-display region of a splicing screen, and improving a user's experience.

Technical solutions of the present application are described in combination with specific embodiments.

### Embodiment 1

Referring to FIG. 1 to FIG. 4, the display panel comprises a first substrate 110; a second substrate 120; and a first connection line 161 and a second connection line 162, both of which are connected with the first substrate 110 and the second substrate 120.

The first substrate 110 includes an array layer 112 on the first base 120.

An insulating layer 150 is located on the array layer 112.

Scan lines 131, data lines 132, a first lead 133, and a second lead 134 are located on the array layer 112 and the insulating layer 150.

A light emitting device 140 is located on the scan lines 131 and the data lines 132.

A packaging layer 160 is located on the array layer 112, the insulating layer 150, the scan lines 131, the data lines 132, and the light emitting device 140.

The second substrate 210 comprises a second base 220 and a second power line layer 230 at a side of the second base 220 away from the light emitting device 140.

The second power line layer 230 comprises: a first fan-out wiring region comprising first fan-out wirings 241 and a third lead 242 located at a third edge 221 of the second substrate 210; and a second fan-out wiring region including second fan-out wirings 251 and a fourth lead 252 located at a fourth edge 222 of the second substrate 210.

The first connection line 161 is located on a side vertical surface of the first base 120 along the first edge 121 to electrically connect the first lead 133 to the fourth lead 252.

The second connection line 162 is located on a side vertical surface of the second base 220 along the second edge 122 to electrically connect the second lead 134 to the third lead 242.

In this embodiment, one of the scan lines 131 is electrically connected to a drain of the array layer 150. The scan lines 131 and the data lines 132 are electrically connected to the light emitting device 140. A voltage is changed by the scanning lines, and then a light emitting brightness of the light emitting device is changed to achieve different display effects.

In this embodiment, the display panel 100 further comprises: a flip-chip thin film 260 on a side of the first fan-out wiring region and the second fan-out wiring region away from the second base 220; and a printed circuit board 270 on the flip-chip thin film 260. Taking the second fan-out wirings 251 in the second fan-out wiring region as an example, please refer to FIG. 1 for details. Electrical connection and circuit control are provided for the display panel 100.

In the present embodiment, the first lead 133 is vertically drawn from the first edge 121 and is collinear with one of the scan lines 131. The second lead 134 is vertically drawn from the second edge 122 and is collinear with one of the data lines 132. The third lead 242 is vertically drawn from the third edge 221 and is electrically connected to one of the first fan-out wirings 241. The fourth lead 252 is vertically drawn from the fourth edge 222 and is electrically connected to one of the second fan-out wirings 251. Please refer to FIG. 1 to FIG. 3 for details. The leads are drawn vertically from the edges of the display panel, which can better arrange and manage the lines, facilitate the connection of the leads and the connecting lines, and realize a frameless design of the display panel.

In the present embodiment, the first edge 121 is vertical to the second edge 122, and the third edge 221 is vertical to the fourth edge 222. The first edge 121 is aligned with the fourth edge 222, and the second edge 122 is aligned with the third edge 221. Please refer to FIG. 1 to FIG. 4 for details. The edges of the two leads of a same substrate are vertical to each other, and the edges of the aligned leads of the two substrates are aligned to each other, which is convenient for producing and fabricating, so as to facilitate an alignment of the two substrates and to avoid problems such as poor contact caused by inaccurate bonding.

In the present embodiment, the first lead 133 and the fourth lead 252 are symmetrical with respect to a symmetry plane 111 of the first base 120 and the second base 220. The second lead 134 and the third lead 242 are symmetrical with respect to the symmetry plane 111 of the first base 120 and the second base 220. Please refer to FIG. 4 for details. The aligned leads are arranged symmetrically in a mirror way, which is beneficial to alignment and bonding, so as to ensure a connection effect, improve the yield, eliminate a frame of the display panel, and ensure a screen display effect.

In the present embodiment, length of the first lead 133, the second lead 134, the third lead 242, and the fourth lead 252 is smaller than a pitch between two adjacent light emitting devices 140. A black non-light emitting region of a display panel splicing gap is reduced to improve a visual effect of a user.

In the present embodiment, the length of the first lead 133, the second lead 134, the third lead 242, and the fourth lead 252 is smaller than one half of the pitch of the two adjacent light emitting devices 140. It can better reduce the black non-light emitting region of the splicing gap when the display panel is spliced, and better realize a seamless visual effect of the entire screen.

In the present embodiment, a bonding adhesive is provided between the first substrate 110 and the second substrate 210, so as to improve an aligning and bonding effect of the two substrates to better reduce the side frame, thereby reducing the black non-light-emitting region of the screen and achieving a good large-screen visual effect.

In the present embodiment, the light emitting device 140 comprises micro-LED and mini-LED. The light emitting device 140 is not limited, and a light emitting device that can independently emit light can be used as the light emitting device.

In Embodiment 1, fan-out wirings are provided on a back of the display panel, and data lines and scan lines on a front of the display panel are electrically connected to the fan-out wirings through leads and connection lines, thereby realizing a frameless design of the display panel, facilitating the display panel splicing, reducing a black non-display region of a splicing screen, and improving a user's experience.

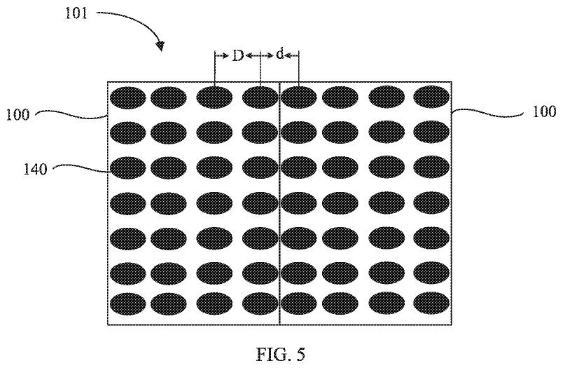

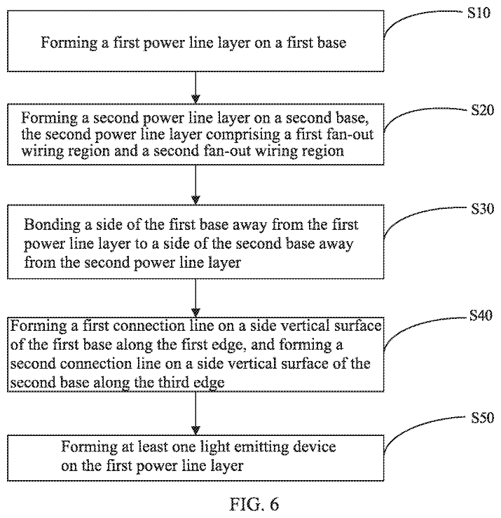

Referring to FIG. 5, the present application further provides a display device 101.

The display device 101 comprises at least two display panels 100, wherein a pitch d between two adjacent light emitting devices 140 between two adjacent display panels 100 is smaller than a pitch D between the two adjacent light emitting devices 140 in any one of the display panels 100. Please refer to FIG. 5 for details.

This application reduces the black non-light-emitting region at the display panel splicing in the display device by setting the pitch between two adjacent pixels of two adjacent display panels of the present application smaller than the pitch between any two adjacent pixels in the display panel, so as to improve the display effect of the display device.

Technical solutions of the present application are described in combination with specific embodiments.

### Embodiment 2

Referring to FIG. 5, the display device 101 comprises at least two display panels 100, wherein a pitch d between two adjacent light emitting devices 140 between two adjacent display panels 100 is smaller than a pitch D between the two adjacent light emitting devices 140 in any one of the display panels 100.

In the present embodiment, the light emitting device 140 comprises micro-LED and mini-LED. The light emitting device 140 is not limited, and a light emitting device that can independently emit light can be used as the light emitting device.

In this embodiment, the display device 101 is formed by splicing at least two of the display panels 100. The display panel 100 is rectangular, and the display device 101 is rectangular. The rectangular display panel 100 can better expand the splicing and realize a multi-size large-screen display device.

The Embodiment 2 reduces the black non-light-emitting region at the display panel splicing in the display device by setting the pitch between two adjacent pixels of two adjacent display panels of the present application smaller than the pitch between any two adjacent pixels in the display panel, so as to improve the display effect of the display device.

Referring to FIG. 6, the present application further provides a method of fabricating a display panel 100, comprising steps of:

In step S10, a first power line layer 130 is formed on a first base 120, wherein the first power line layer 130 comprises a first lead 133 located at a first edge 121 of the first base 120 and a second lead 134 located at a second edge 122 of the first base 120.

In step S20, a second power line layer 230 is formed on a second base 220. The second power line layer 230 comprises a first fan-out wiring region and a second fan-out wiring region, wherein the first fan-out wiring region comprises first fan-out wirings 241 and a third lead 242 located at a third edge 221 of the second base 220; and the second fan-out wiring region comprises second fan-out wirings 251 and a fourth lead 252 located at a fourth edge 222 of the second base 220.

In step S30, a side of the first base 120 away from the first power line layer 130 is bonded to a side of the second base 220 away from the second power line layer 230.

In step S40, a first connection line 161 is formed on a side vertical surface of the first base 120 along the first edge 121 to electrically connect the first lead 133 to the fourth lead 252, and a second connection line 162 is formed on a side vertical surface of the second base 220 along the third edge 221 to electrically connect the second lead 134 to the third lead 242.

In step S50, at least one light emitting device 140 is formed on the first power line layer 130.

In the present application, fan-out wirings are provided on a back of the display panel, and power lines on a front of the display panel are electrically connected to the fan-out wirings through leads and connection lines, thereby realizing a frameless design of the display panel, facilitating the display panel splicing, reducing a black non-display region of a splicing screen, and improving a user's experience.

Technical solutions of the present application are described in combination with specific embodiments.

### Embodiment 3

In step S10, a first power line layer 130 is formed on a first base 120, wherein the first power line layer 130 comprises a first lead 133 located at a first edge 121 of the first base 120 and a second lead 134 located at a second edge 122 of the first base 120.

In the present embodiment, the step of forming the first power line layer 130 on the first base 120 comprises:

In step S11, scan lines 131 insulated from each other along a first direction are formed on the first base 120, and the first lead 133 extending from one of the scan lines 131 and vertical to the first edge 121 of the first base 120 are formed.

In this embodiment, the first direction is an X-axis direction. Please refer to FIG. 2 for details.

In step S12, data lines 132 insulated from each other along a second direction are formed on the first base 120, and the second lead 134 extending from one of the data lines 132 and vertical to the second edge 122 of the first base 120 are formed.

In this embodiment, the first direction is a Y-axis direction. Please refer to FIG. 2 for details.

The first edge 121 is vertical to the second edge 122. Please refer to FIG. 2 for details.

The leads extend from the data lines and the scanning lines, which facilitates an electrical connection among the data lines, the power lines, and the fan-out wirings. The leads are drawn vertically from the edges of the first base, which can better arrange and manage the lines, facilitate the connection of the leads and the connecting lines, and realize a frameless design of the display panel. The edges of the two leads of a same substrate are vertical to each other, which is convenient for producing and fabricating, so as to facilitate an alignment of the two substrates and to avoid problems such as poor contact caused by inaccurate bonding.

In this embodiment, a method of fabricating the first power line layer 130 includes a low temperature polysilicon method and a metal oxide method.

In step S20, a second power line layer 230 is formed on a second base 220. The second power line layer 230 comprises a first fan-out wiring region and a second fan-out wiring region, wherein the first fan-out wiring region comprises first fan-out wirings 241 and a third lead 242 located at a third edge 221 of the second base 220; and the second fan-out wiring region comprises second fan-out wirings 251 and a fourth lead 252 located at a fourth edge 222 of the second base 220.

In this embodiment, the step of forming the second power line layer 230 on the second base 220 includes:

The first fan-out wirings 241 insulated from each other are formed on the second base 220, and the third lead 242 extending from one of the first fan-out wirings 241 and vertical to the third edge 221 of the second base 220 are formed.

The second fan-out wirings 251 insulated from each other are formed on the second base 220, and the fourth lead 252 extending from one of the second fan-out wirings 251 and vertical to the fourth edge 222 of the second base 220 are formed.

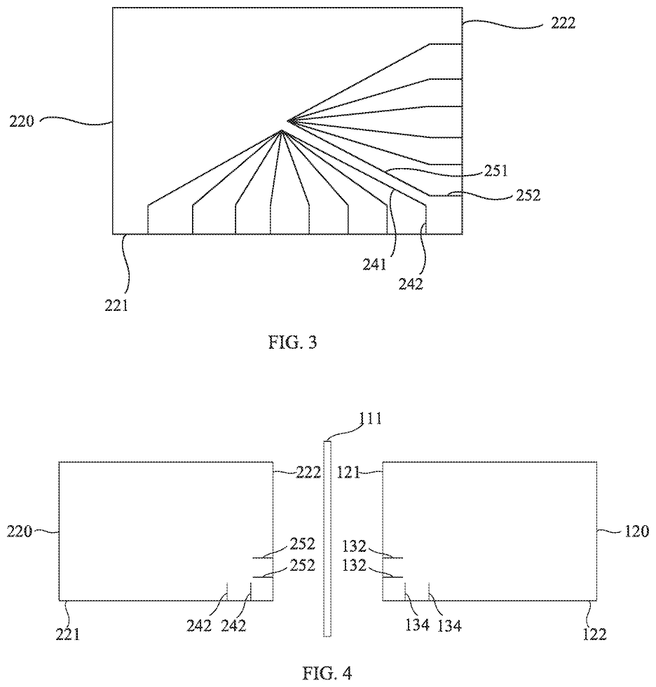

The third edge 221 is vertical to the fourth edge 222, the first edge 121 is aligned with the fourth edge 222, and the second edge 122 is aligned with the third edge 221. The first lead 133 and the fourth lead 252 are symmetrical with respect to a symmetry plane 111 of the first base 120 and the second base 220, and the second lead 134 and the third lead 242 are symmetrical with respect to the symmetry plane 111 of the first base 120 and the second base 220. Please refer to FIG. 3 and FIG. 4 for details.

The leads extend from the fan-out wirings, which facilitates an electrical connection among the fan-out wirings, the data lines, and the power lines. The leads are drawn vertically from the edges of the second base, which can better arrange and manage the lines, facilitate the connection of the leads and the connecting lines, and realize a frameless design of the display panel. The edges of the two leads of a same substrate are vertical to each other, and the edges of the aligned leads of the two substrates are aligned to each other, which is convenient for producing and fabricating, so as to facilitate an alignment of the two substrates and to avoid problems such as poor contact caused by inaccurate bonding to affect display effects. The aligned leads are arranged symmetrically in a mirror way, which is beneficial to alignment and bonding, so as to ensure a connection effect, improve the yield, and ensure a screen display effect.

In step S30, a side of the first base 120 away from the first power line layer 130 is bonded to a side of the second base 220 away from the second power line layer 230.

In this embodiment, a material used in the bonding process includes a bonding glue, and a glue layer is formed between the first substrate and the second substrate. Increase the registration effect of the two substrates, reduce the frame better, and achieve a good large-screen visual effect. The registration effect of the two substrates are improved, the side frame is better reduced, and a good large-screen visual effect is achieved.

In step S40, a first connection line 161 is formed on a side vertical surface of the first base 120 along the first edge 121 to electrically connect the first lead 133 to the fourth lead 252, and a second connection line 162 is formed on a side vertical surface of the second base 220 along the third edge 221 to electrically connect the second lead 134 to the third lead 242.

In step S50, at least one light emitting device 140 is formed on the first power line layer 130.

In the present embodiment, the light emitting device 140 comprises micro-LED and mini-LED. The light emitting device 140 is not limited, and a light emitting device that can independently emit light can be used as the light emitting device.

In this embodiment, a method of fabricating the display panel 100 further includes:

In step S60, a circuit board layer is formed on the second power line layer 230.

In the present embodiment, the circuit board layer comprises a flip-chip thin film 260 and a printed wiring board 270. Please refer to FIG. 1 for details. In this embodiment, the flip-chip thin film 260 and the printed wiring board 270 are disposed on a back of the display panel, and the side frame of the display panel is eliminated on the premise of ensuring the electrical connection and circuit control of the display panel.

In Embodiment 3, a display region and the aligned leads are formed on the first base, a fan-out wiring region and the aligned leads are formed on the second base. Further, the two substrates are aligned and bonded to each other to form the aligned connection lines so as to electrically connect the power lines of the display region with the fan-out wirings, thereby realizing a frameless design of the display panel, facilitating the display panel splicing, reducing a black non-display region of a splicing screen, and improving a user's experience.

The present application discloses a display panel and a method of fabricating the same, and a display device. The display panel comprises: a first substrate comprising a first lead at a first edge of the first substrate and a second lead at a second edge of the first substrate; a second substrate comprising a third lead at a third edge of the second substrate and a fourth lead at a fourth edge of the second substrate; and connection lines connected the first lead to the fourth lead and connected the second lead to the third lead. In the present application, fan-out wirings are provided on a back of the display panel, and data lines and scan lines are electrically connected to the fan-out wirings through leads and connection lines, thereby realizing a frameless design of the display panel, facilitating the display panel splicing, reducing a black non-display region of a splicing screen, and improving a user's experience.

It can be understood that, for a person of ordinary skill in the art, equivalent replacements or changes can be made according to the technical solution and its inventive concept of the present application. All these changes or replacements should fall within the protection scope of the claims attached to this application.

1. A display panel, comprising:
a first substrate comprising a first base, a first power line layer on the first base, and at least one light emitting device on the first power line layer, wherein the first power line layer comprises:
a first lead located at a first edge of the first base; and
a second lead located at a second edge of the first base;
a second substrate located at a side of the first substrate away from the light emitting device and comprising a second base and a second power line layer at a side of the second base away from the light emitting device, wherein the second power line layer comprises:
a first fan-out wiring region comprising first fan-out wirings and a third lead located at a third edge of the second substrate; and
a second fan-out wiring region comprising second fan-out wirings and a fourth lead located at a fourth edge of the second substrate;
a first connection line located on a side vertical surface of the first base along the first edge to electrically connect the first lead to the fourth lead; and
a second connection line located on a side vertical surface of the second base along the second edge to electrically connect the second lead to the third lead.

2. The display panel according to claim 1, wherein:
the first lead is vertically drawn from the first edge and is collinear with a scan line in the first power line layer;
the second lead is vertically drawn from the second edge and is collinear with a data line in the first power line layer;
the third lead is vertically drawn from the third edge and is electrically connected to one of the first fan-out wirings;
the fourth lead is vertically drawn from the fourth edge and is electrically connected to one of the second fan-out wirings;
the first edge is vertical to the second edge, and the third edge is vertical to the fourth edge; and
the first edge is aligned with the fourth edge, and the second edge is aligned with the third edge.

3. The display panel according to claim 2, wherein:
the first lead and the fourth lead are symmetrical with respect to a symmetry plane of the first base and the second base; and
the second lead and the third lead are symmetrical with respect to the symmetry plane of the first base and the second base.

4. The display panel according to claim 1, wherein length of the first lead, the second lead, the third lead, and the fourth lead is smaller than a pitch between two adjacent light emitting devices.

5. The display panel according to claim 1, wherein the light emitting device comprises micro-LED and mini-LED.

6. The display panel according to claim 1, further comprising a circuit board layer on the second power line layer,
wherein the circuit board layer comprises a flip-chip thin film and a printed wiring board.

7. A display device, comprising at least two display panels,
wherein each of the display panels comprises:
a first substrate comprising a first base, a first power line layer on the first base, and at least one light emitting device on the first power line layer, wherein the first power line layer comprises:
a first lead located at a first edge of the first base; and
a second lead located at a second edge of the first base;
a second substrate located at a side of the first substrate away from the light emitting device and comprising a second base and a second power line layer at a side of the second base away from the light emitting device, wherein the second power line layer comprises:
a first fan-out wiring region comprising first fan-out wirings and a third lead located at a third edge of the second substrate; and
a second fan-out wiring region, comprising second fan-out wirings and a fourth lead located at a fourth edge of the second substrate;
a first connection line located on a side vertical surface of the first base along the first edge to electrically connect the first lead to the fourth lead; and
a second connection line located on a side vertical surface of the second base along the second edge to electrically connect the second lead to the third lead.

8. The display device according to claim 7, wherein:
the first lead is vertically drawn from the first edge and is collinear with a scan line in the first power line layer;
the second lead is vertically drawn from the second edge and is collinear with a data line in the first power line layer;
the third lead is vertically drawn from the third edge and is electrically connected to one of the first fan-out wirings;
the fourth lead is vertically drawn from the fourth edge and is electrically connected to one of the second fan-out wirings;
the first edge is vertical to the second edge, and the third edge is vertical to the fourth edge; and
the first edge is aligned with the fourth edge, and the second edge is aligned with the third edge.

9. The display device according to claim 8, wherein:
the first lead and the fourth lead are symmetrical with respect to a symmetry plane of the first base and the second base; and
the second lead and the third lead are symmetrical with respect to the symmetry plane of the first base and the second base.

10. The display device according to claim 7, wherein length of the first lead, the second lead, the third lead, and the fourth lead is smaller than a pitch between two adjacent light emitting devices.

11. The display device according to claim 7, wherein the light emitting device comprises micro-LED and mini-LED.

12. The display device according to claim 7, wherein each of the display panels further comprises a circuit board layer on the second power line layer,
wherein the circuit board layer comprises a flip-chip thin film and a printed wiring board.

13. The display device according to claim 7, wherein a pitch between two adjacent light emitting devices between two adjacent display panels is smaller than a pitch between the two adjacent light emitting devices in any one of the display panels.

14. A method of fabricating a display panel, comprising steps of:
forming a first power line layer on a first base, wherein:
the first power line layer comprises a first lead located at a first edge of the first base and a second lead located at a second edge of the first base;
forming a second power line layer on a second base, the second power line layer comprising a first fan-out wiring region and a second fan-out wiring region, wherein:
the first fan-out wiring region comprises first fan-out wirings and a third lead located at a third edge of the second base; and the second fan-out wiring region comprises second fan-out wirings and a fourth lead located at a fourth edge of the second base;
bonding a side of the first base away from the first power line layer to a side of the second base away from the second power line layer;
forming a first connection line on a side vertical surface of the first base along the first edge to electrically connect the first lead to the fourth lead, and forming a second connection line on a side vertical surface of the second base along the third edge to electrically connect the second lead to the third lead; and
forming at least one light emitting device on the first power line layer.

15. The method of fabricating the display panel according to claim 14, wherein the step of forming the first power line layer on the first base comprises:
forming scan lines insulated from each other along a first direction on the first base, and forming the first lead extending from one of the scan lines and vertical to the first edge of the first base; and
forming data lines insulated from each other along a second direction on the first base, and forming the second lead extending from one of the data lines and vertical to the second edge of the first base,
wherein the first edge is vertical to the second edge.

16. The method of fabricating the display panel according to claim 14, wherein the step of forming the second power line layer on the second base comprises:
forming the first fan-out wirings insulated from each other on the second base, and forming the third lead extending from one of the first fan-out wirings and vertical to the third edge of the second base; and
forming the second fan-out wirings insulated from each other on the second base, and forming the fourth lead extending from one of the second fan-out wirings and vertical to the fourth edge of the second base, wherein the third edge is vertical to the fourth edge, the first edge is aligned with the fourth edge, and the second edge is aligned with the third edge; and
the first lead and the fourth lead are symmetrical with respect to a symmetry plane of the first base and the second base, and the second lead and the third lead are symmetrical with respect to the symmetry plane of the first base and the second base.

17. The method of fabricating the display panel according to claim 14, wherein length of the first lead, the second lead, the third lead, and the fourth lead is smaller than a pitch between two adjacent light emitting devices.

18. The method of fabricating the display panel according to claim 14, further comprising steps of:
forming a circuit board layer on the second power line layer, wherein the circuit board layer comprises a flip-chip thin film and a printed wiring board.

19. The method of fabricating the display panel according to claim 14, wherein the light emitting device comprises micro-LED and mini-LED.
